(19) United States
(12) Patent Application Publication
(10) Pub. No.: US 2026/0028689 A1
(43) Pub. Date: Jan. 29, 2026

(54) EMISSIVE LINER ARRANGEMENTS FOR ANNEALING OPERATIONS, AND RELATED PROCESS CHAMBERS, SYSTEMS, COMPONENTS, AND METHODS

(71) Applicant: Applied Materials, Inc., Santa Clara, CA (US)

(72) Inventors: Dongming IU, Union City, CA (US); Matthew SPULLER, Belmont, CA (US); Victor CALDERON, Santa Clara, CA (US)

(21) Appl. No.: 19/018,642

(22) Filed: Jan. 13, 2025

Related U.S. Application Data
(60) Provisional application No. 63/676,726, filed on Jul. 29, 2024.
(60) Provisional application No. 63/686,515, filed on Aug. 23, 2024.

(51) Int. Cl. C21D 9/00; C21D 11/00; H01L 21/67

(52) U.S. Cl. CPC C21D 9/0006; C21D 11/00; H01L 21/67103

(57) ABSTRACT

Aspects of the present disclosure relate to emissive liner arrangements for annealing operations, and related process chambers, systems, components, and methods. In one or more embodiments, an emissive liner arrangement facilitates annealing substrates at an annealing temperature less than 210 degrees Celsius. In one or more embodiments, a processing chamber includes a chamber body at least partially defining a process volume, a substrate support disposed in the process volume, the substrate support including one or more heater elements, and one or more liners disposed between the substrate support and a section of the chamber body. The one or more liners respectively include a ring or a ring segment having an azimuthal length that is 80 degrees or higher. The processing chamber includes a plasma source operable to supply a plasma to the process volume.

### CROSS-REFERENCE TO RELATED APPLICATIONS

This application claims priority to U.S. Provisional Application Ser. No. 63/676,726, filed Jul. 29, 2024, and U.S. Provisional Application Ser. No. 63/686,515, filed Aug. 23, 2024, each of which is herein incorporated by reference in its entirety.

### BACKGROUND

### Field

Aspects of the present disclosure relate to emissive liner arrangements for annealing operations, and related process chambers, systems, components, and methods.

### Description of the Related Art

Substrates for semiconductor operations can be limited in operation. For example, processing operations (such as annealing operations) can involve temperature non-uniformities, which can cause processing non-uniformities. For example, central regions of substrates can be colder than edge regions of substrates. It can also be difficult to process substrates at low temperatures. For example, heaters can be unstable at low temperatures, which can cause ineffective heating.

Therefore, there is a need for improved methods, systems, and apparatus that facilitate thermal adjustability.

### SUMMARY

Aspects of the present disclosure relate to emissive liner arrangements for annealing operations, and related process chambers, systems, components, and methods. In one or more embodiments, an emissive liner arrangement facilitates annealing substrates at an annealing temperature less than 210 degrees Celsius.

In one or more embodiments, a processing chamber includes a chamber body at least partially defining a process volume, a substrate support disposed in the process volume, the substrate support including one or more heater elements, and one or more liners disposed between the substrate support and a section of the chamber body. The one or more liners respectively include a ring or a ring segment having an azimuthal length that is 80 degrees or higher. The processing chamber includes a plasma source operable to supply a plasma to the process volume.

In one or more embodiments, a liner for disposition in a processing chamber includes a body having an azimuthal length that is 80 degrees or higher. The body is formed of an anodized aluminum, and the body has a width that is greater than a thickness. The width is a ratio of the thickness, and the ratio is at least 2.0.

In one or more embodiments, a system for processing substrates includes a processing chamber. The processing chamber includes a chamber body at least partially defining a process volume, a substrate support disposed in the process volume, the substrate support including one or more heater elements, and one or more liners disposed between the substrate support and a section of the chamber body. The processing chamber includes a plasma source. The system includes a controller including a processor and a memory including instructions that, when executed by the processor, cause a plurality of operations to be conducted. The plurality of operations include positioning a substrate on the substrate support, and annealing the substrate. The annealing includes exposing the substrate to a plasma, and exposing the substrate to an anneal temperature that is less than 210 degrees Celsius. The annealing includes exposing the substrate for an anneal time that is less than 4.0 minutes.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic top-view diagram of a system for processing substrates, according to one or more embodiments.

FIG. 2A is a schematic partial view of a system for thermally annealing substrates, according to one or more embodiments.

FIG. 2B is a schematic view of the system shown in FIG. 2A in a twin chamber configuration, according to one or more embodiments.

FIG. 3 is a schematic partial view of a system for processing substrates, according to one or more embodiments.

FIG. 4 is a schematic block diagram view of a method of substrate processing for semiconductor manufacturing, according to one or more embodiments.

FIG. 5 is a schematic partial top view of a plurality of liners in the chamber, to one or more embodiments.

FIG. 6 is a schematic partial top view of a plurality of liners in the chamber, according to one or more embodiments.

FIG. 7 is a schematic top view of a C-ring liner in the chamber, according to one or more embodiments.

FIG. 8 is a schematic top view of a C-ring liner, according to one or more embodiments.

FIG. 9 is a schematic top view of an L-shaped liner, according to one or more embodiments.

FIG. 10 is a schematic power-versus-time graph for power of a heater (such as an outer heater corresponding to an edge region of a substrate) for a chamber using liners described herein, according to one or more embodiments.

FIG. 11 is a schematic power-versus-time graph for power of a heater (such as an outer heater corresponding to an edge region of a substrate) for a chamber using another configuration.

FIG. 12 is a schematic temperature map of a substrate annealed in a chamber using liners described herein, according to one or more embodiments.

FIG. 13 is a schematic temperature map of a substrate annealed in a chamber another configuration.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects of the present disclosure relate to emissive liner arrangements for annealing operations, and related process chambers, systems, components, and methods. In one or more embodiments, an emissive liner arrangement facilitates annealing substrates at an annealing temperature less than 210 degrees Celsius. In one or more embodiments, a liner is omitted for a side of the process volume that corresponds to a slit valve of the process chamber.

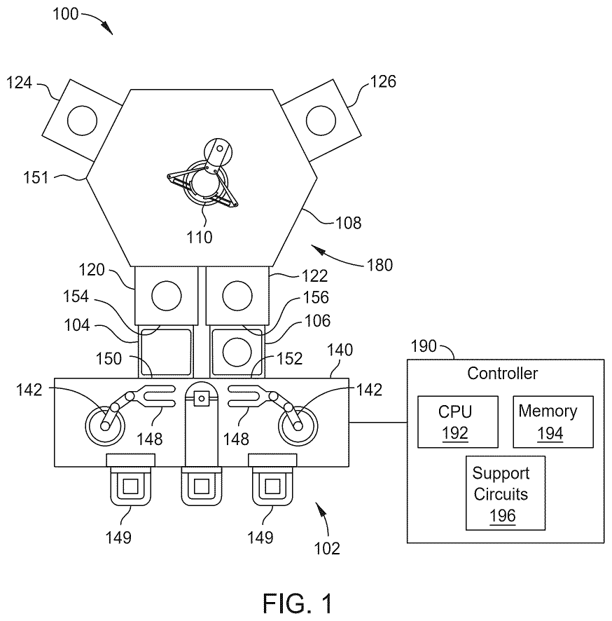

FIG. 1 is a schematic top-view diagram of a system 100 for processing substrates, according to one or more embodiments. The system 100 includes a cluster tool 180. The cluster tool 180 includes a factory interface 102, one or more transfer chambers 108 (one is shown) with a transfer robot 110 disposed therein. The cluster tool 180 includes one or more first chambers 120, 122 (two are shown) and one or more second chambers 124, 126 (two are shown) mounted to a mainframe 151 of the single cluster tool 180. The one or more first chambers 120, 122 are radical treatment chambers that are each configured to conduct a radical treatment operation on substrates. The one or more second chambers 124, 126 are anneal chambers that are each configured to conduct an annealing operation on substrates.

As detailed herein, substrates in the system 100 can be processed in and transferred between the various chambers without being exposed to an ambient environment exterior to the cluster tool 180. For example, substrates can be processed in and transferred between the various chambers in a low pressure (e.g., 550 Torr or less) or vacuum environment (e.g., 20 Torr or less) without breaking the low pressure or vacuum environment between various processes performed on the substrates in the system 100. In one or more embodiments, the system 100 provides an integrated cluster tool 180 for conducting processing operations on substrates.

In the implementation shown in FIG. 1, the factory interface 102 includes a docking station 140 and factory interface robots 142 to facilitate transfer of substrates. The docking station 140 is configured to accept one or more front opening unified pods (FOUPs) 149. In one or more embodiments, each factory interface robot 142 includes a blade 148 disposed on one end of the respective factory interface robot 142 configured to transfer substrates from the factory interface 102 to the load lock chambers 104, 106.

The load lock chambers 104, 106 have respective doors 150, 152 interfacing with the factory interface 102 and respective doors 154, 156 interfacing with the one or more first chambers 120, 122. The one or more first chambers 120, 122 have respective doors interfacing with the transfer chamber 108, and the one or more second chambers 124, 126 have respective doors interfacing with the transfer chamber 108.

The doors can include, for example, slit openings with slit valves for passing substrates therethrough by the transfer robot 110 and for providing a seal between respective chambers to prevent a gas from passing between the respective chambers. A door can be open for transferring a substrate therethrough, and otherwise closed.

The load lock chambers 104, 106, the transfer chamber 108, the first chambers 120, 122, and the second chambers 124, 126 may be fluidly coupled to a gas and pressure control system. The gas and pressure control system can include one or more gas pumps (e.g., turbo pumps, cryo-pumps, roughing pumps, vacuum pumps, etc.), gas sources, various valves, and conduits fluidly coupled to the various chambers.

The system 100 includes a controller 190 configured to control the system 100 or components thereof. For example, the controller 190 may control the operation of the system 100 using a direct control of the chambers 104, 106, 108, 120, 122, 124, 126 of the system 100 or by controlling controllers associated with the chambers 104, 106, 108, 120, 122, 124, 126. The controller 190 is configured to control the gas and pressure control system. In operation, the controller 190 enables data collection and feedback from the respective chambers and the gas and pressure control system to coordinate and control performance of the system 100.

The controller 190 generally includes a central processing unit (CPU) 192, a memory 194, and support circuits 196. The CPU 192 may be one of any form of a general purpose processor that can be used in an industrial setting. The memory 194, or non-transitory computer readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may include cache, clock circuits, input/output subsystems, power supplies, and the like.

The various methods (such as the method 400) and operations disclosed herein may generally be implemented under the control of the CPU 192 by the CPU 192 executing computer instruction code stored in the memory 194 (or in memory of a particular processing chamber) as, e.g., a software routine. When the computer instruction code is executed by the CPU 192, the CPU 192 controls the chambers to conduct processes in accordance with the various methods and operations described herein. In one or more embodiments, the memory 194 includes instructions stored therein that, when executed, cause the methods (such as the method 400) and operations (such as the operations 402, 403a, 403b, 404, 406, 408) described herein to be conducted.

Other processing systems in other configurations are contemplated. For example, more or fewer processing chambers may be coupled to a transfer apparatus. In the implementation shown in FIG. 1, the transfer apparatus includes the transfer chamber 108. In other implementations, more or fewer transfer chambers (e.g., one transfer chamber) may be implemented as a transfer apparatus in a system for processing substrates.

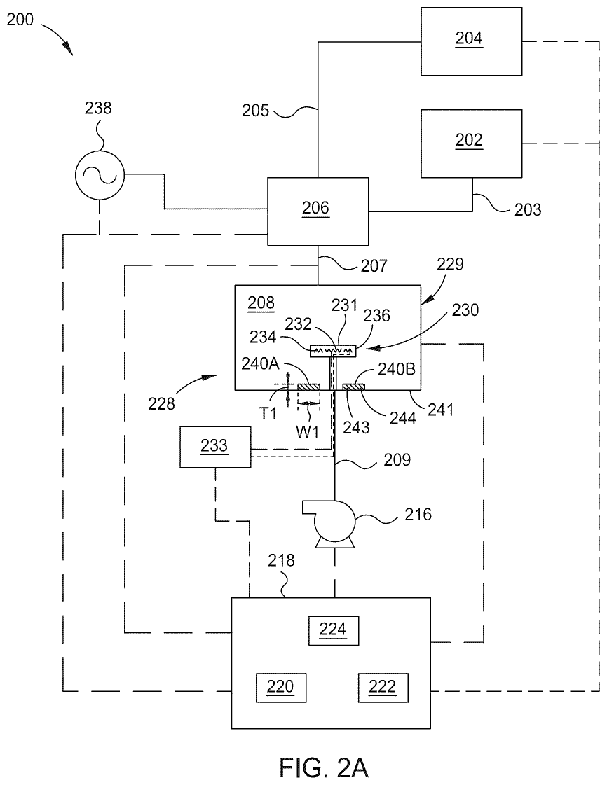

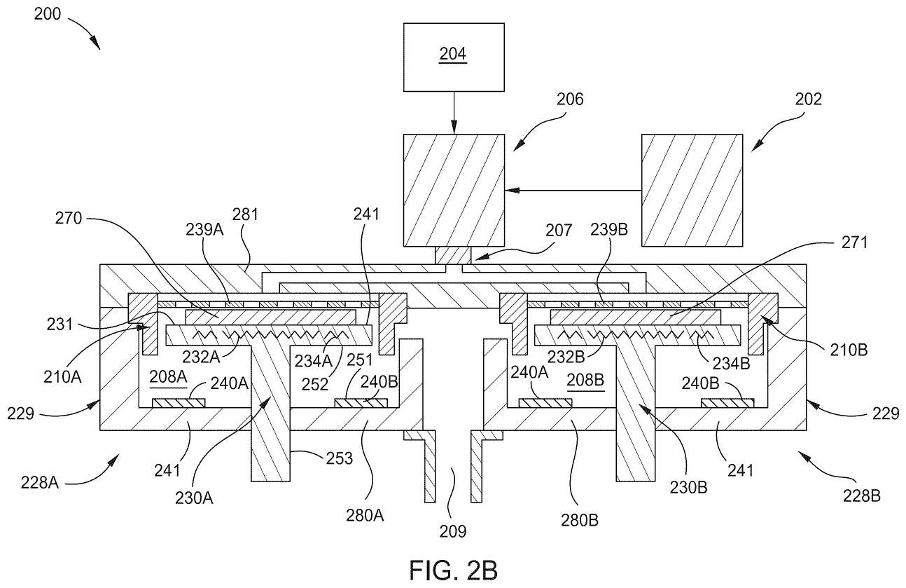

FIG. 2A is a schematic partial view of a system 200 for thermally annealing substrates, according to one or more embodiments. The system 200 includes a process chamber 228, such as the PYRA® chamber available from Applied Materials, Inc. of Santa Clara, Calif.

The system 200 can be used as at least part of each of the one or more second chambers 124, 126 shown in FIG. 1 that are configured to conduct the annealing operation.

The system 200 includes a remote plasma source (RPS) 206, and a gas line 207 coupling the remote plasma source 206 to the process chamber 228. The present disclosure contemplates that in an in-situ plasma operation may be used in place of the RPS 206. The process chamber 228 can be used as at least part of each of the one or more second chambers 124, 126 shown in FIG. 1. The process chamber 228 can be a heater based process chamber, or a rapid thermal processing (RTP) chamber, such as a rapid thermal anneal (RTA) chamber. The process chamber 228 can be any thermal processing chamber, for example any thermal processing chamber where delivery of at least one metastable radical molecular species and/or radical atomic species to a processing volume can be used. The process chamber 228 includes a substrate support, such as a pedestal heater 230. Other substrate supports, such as ring supports, are contemplated. The pedestal heater 230 includes a base platform that includes a support surface 231. The support surface 231 is circular or rectangular in shape. The pedestal heater 230 includes one or more heater elements 232, 234 embedded in the pedestal heater 230. The one or more heater elements 232, 234 include one or more resistive heater elements, such as wire mesh(es) and/or resistive heating coil(s). In one or more embodiments, the one or more heater elements 232, 234 include an inner heater element 232 and an outer heater element 234 disposed radially outward of the inner heater element 232. The pedestal heater 230 includes a ceramic or aluminum body with the one or more heater elements 232, 234 embedded in the ceramic or aluminum body. The one or more heater elements 232, 234 are connected to a power source 233 that supplies power, such as electrical power (for example direct current or alternating current), to the one or more heater elements 232, 234. The one or more heater elements 232, 234 and the pedestal heater 230 are used to heat and control a temperature of a substrate (disposed on the pedestal heater 230) and a film stack of the substrate.

The RPS 206 is coupled to a power source 238. The power source 238 is used as an excitation source to ignite and maintain a plasma in the RPS 206. In one or more embodiments, the RPS 206 includes an inductively coupled plasma (ICP) source, a transformer coupled plasma (TCP) source, and/or a capacitively coupled plasma (CCP) source. In one or more embodiments, the power source 238 is a radio frequency (RF) source. In one or more examples, the RF source delivers power between about 5 kW to about 9 kW, such as about 7 kW. In one or more embodiments, the RPS 206 includes one or more microwave resonators.

The RPS 206 is coupled to a first gas source 202 via a first gas conduit 203 and a second gas source 204 via a second gas conduit 205. The first gas source 202 supplies a first gas that includes one or more of hydrogen, oxygen, argon, and/or nitrogen. The flow rate of the first gas into the processing volume 208 is within a range of about 10 sccm to about 100,000 sccm. In one or more embodiments, nitrogen is supplied at a flow rate within a range of 10 sccm to 50,000 sccm, oxygen is supplied at a flow rate within a range of 10 sccm to 30,000 sccm, hydrogen is supplied at a flow rate within a range of 10 sccm to 50,000 sccm, and/or argon is supplied at a flow rate within a range of 10 sccm to 50,000 sccm.

The second gas source 204 supplies a second gas, such as oxygen gas. Oxygen plasma is formed using the RPS 206 by introducing about 1 sccm to about 50,000 sccm of oxygen gas, such as about 10 sccm to 50,000 sccm of oxygen gas introduced to the processing volume 208.

A vacuum pump 216 is used to maintain a gas pressure in the processing volume 208. The vacuum pump 216 evacuates post-processing gases and/or by-products of the process via an exhaust 209.

The one or more liners 240A, 240B can be made from quartz, ceramic, and/or metal. In one or more embodiments, the one or more liners 240A, 240B are formed of anodized aluminum (such as Type 3 anodized aluminum). Other materials are contemplated for the one or more liners 240A, 240B. For example, the one or more liners 240A, 240B can include one or more of silicon carbide (SiC), graphite, and/or opaque quartz (such as black quartz, white quartz, and/or grey quartz). In one or more embodiments, the pedestal heater 230 is formed of a ceramic material, such as aluminum oxide or another ceramic material. Other materials are contemplated for the pedestal heater 230.

The one or more liners 240A, 240B respectively have a width W1 that is greater than a thickness T1. For example, a cross-section of the respective one or more liners 240A, 240B have the width W1 and the thickness T1. The width W1 is a ratio of the thickness T1, and the ratio is at least 2.0. In one or more embodiments, the ratio is 2.5 or higher, 3.0 or higher, 3.5 or higher, or 4.0 or higher. In one or more embodiments, the thickness T1 is within a range of 0.25 inches to 0.5 inches. The one or more liners 240A, 240B have an emissivity that is 0.75 or higher, such as 0.8 or higher. In one or more embodiments, the emissivity is within a range of 0.75 to 0.9. In one or more embodiments the emissivity is 0.9 or higher, such as 0.95 or higher. The thickness T1 can be increased to increase emissivity, for example. The emissivity of the one or more liners 240A, 240B can draw (e.g., absorb) heat from the pedestal heater 230 and emit the heat away from the pedestal heater 230, such as toward a chamber body 229 of the process chamber 228. The one or more liners 240A, 240B are disposed between the pedestal heater 230 and a section of the chamber body 229. In one or more embodiments, the section is a floor section 241 of the chamber body 229. The one or more liners 240A, 240B directly contact the floor section 241. The present disclosure contemplates that the one or more liners 240A, 240B can be supported by one or more standoffs (e.g., stainless steel standoffs or aluminum standoffs) between the one or more liners 240A, 240B and the floor section 241. The standoffs can be cylindrical pins, or other columns, for example.

A surface area 251 (FIG. 2B) of the one or more liners 240A, 240B faces the pedestal heater 230. The surface area 251 of the one or more liners 240A, 240B is greater than 50% of a surface area 252 (FIG. 2B) of the pedestal heater 230. The surface area 252 of the pedestal heater 230 faces the one or more liners 240A, 240B. In one or more embodiments, the surface area 252 of the pedestal heater 230 is radially outward of a shaft 253 supporting the pedestal heater 230. In one or more embodiments, the surface area 251 of the one or more liners 240A, 240B is 100% or less of the surface area 252 of the pedestal heater 230. In one or more embodiments, the surface area 251 of the one or more liners 240A, 240B is within a range of 40 inches² to 150 inches².

The one or more liners 240A, 240B are radially aligned with an outer edge 236 of the pedestal heater 230. For example, any section between an inner radius and an outer radius of the one or more liners 240A, 240B can be radially aligned with the outer edge 236. In one or more embodiments, an inner section 243 of the respective one or more liners 240A, 240B is aligned under the pedestal heater 230, and an outer section 244 of the respective one or more liners 240A, 240B is aligned radially outwardly of the pedestal heater 230.

Alternatively, the process chamber 228 can be employed in a twin chamber configuration as shown in FIG. 2B. FIG. 2B is a schematic view of the system 200 shown in FIG. 2A in a twin chamber configuration, according to one or more embodiments. The twin chamber configuration may be used as at least part of each of the one or more second chambers 124, 126. The twin chamber configuration includes two respective processing regions 228A, 228B that are in fluid communication with each other. The respective processing regions 228A, 228B can be configured to include one or more of the components, features, aspects, and/or properties of the process chamber 228 shown in FIG. 2A.

The respective processing regions 228A, 228B includes a respective lower chamber body 280A, 280B. The present disclosure contemplates that the processing regions 228A, 228B can share the same lower chamber body. The processing regions 228A, 228B share the same upper chamber body 281. The present disclosure contemplates that the processing regions 228A, 228B can each respectively include a distinct upper chamber body.

Each of the processing regions 228A, 228B includes: respective pedestal heaters 230A, 230B similar to the pedestal heater 230; respective one or more heater elements 232A, 232B, 234A, 234B similar to the one or more heater elements 232, 234; respective one or more liners 240A, 240B; and/or respective processing volumes 208A, 208B similar to the processing volume 208. The processing regions 228A, 228B can share a single RPS 206 that provides the first gas (during a thermal anneal operation) and optionally the oxygen plasma (during an optional later clean operation to clean the processing regions 228A, 228B) to the processing volumes 208A, 208B. The RPS 206 is coupled to the first gas source 202 and the second gas source 204. Each of the processing regions 228A, 228B includes a respective process kit 210A, 210B. Each respective process kit 210A, 210B includes one or more components inside the respective one of the processing regions 228A, 228B used for on-substrate performance, such as the one or more liners 240A, 240B.

The processing regions 228A, 228B are coupled to share a single controller (such as the controller 190), or can be coupled to separate controllers. The present disclosure contemplates that portions of the process kits 210A, 210B may move and/or include flow openings to allow the first gas and the oxygen plasma to flow to the exhaust 209. The system 200 can include a valve, disposed for example along the exhaust 209, such that the first gas and the oxygen plasma are not exhausted and are instead directed to the processing volumes 208A, 208B during the thermal anneal operation and the optional later clean operation. Each of the processing regions 228A, 228B includes respective gas distribution plates 239A, 239B.

A first substrate 270 and a second substrate 271 are directly supported respectively on the pedestal heaters 230A, 230B to undergo a thermal anneal operation.

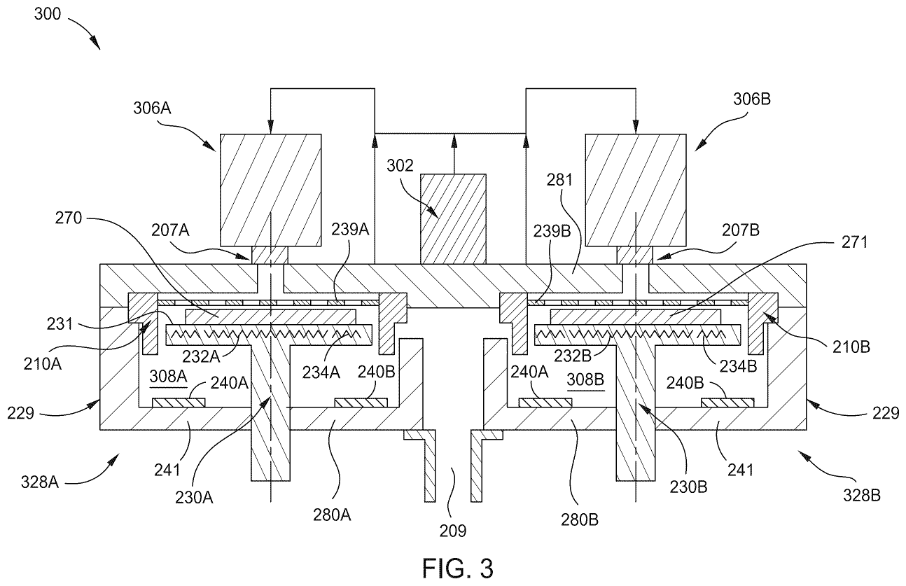

FIG. 3 is a schematic partial view of a system 300 for processing substrates, according to one or more embodiments. The system 300 is similar to the system 200 shown in FIGS. 2A-2B, and includes one or more of the aspects, features, components, and/or properties thereof. The system 300 can be used as at least part of the one or more first process chambers 120, 122 shown in FIG. 1 that are configured to conduct radical treatment operations. The system 300 includes a process chamber having two respective processing regions 328A, 328B. The processing regions 328A, 328B are similar to the processing regions 228A, 228B, and include one or more—but not all—of the aspects, features, components, and/or properties thereof.

The processing regions 328A, 328B respectively include: respective pedestal heaters 230A, 230B similar to the pedestal heater 230; respective remote plasma sources 306A, 306B similar to the RPS 206; respective gas lines 207A, 207B similar to the gas line 207; respective one or more heater elements 232A, 234A, 232B, 234B similar to the one or more heater elements 232, 234; respective one or more liners 240A, 240B; and/or respective processing volumes 308A, 308B similar to the processing volume 208. In one embodiment, which can be combined with other embodiments, the processing regions 328A, 328B can share a single RPS.

The system 300 includes a first gas source 302 similar to the first gas source 202 described above, and can include one or more of the aspects, features, components, and/or properties thereof. In one or more embodiments, each respective RPS 306A, 306B is coupled to share a single first gas source 302. In one or more embodiments, each RPS 306A, 306B can be coupled to a distinct first gas source. The first gas source 302 supplies one or more gases that include hydrogen, oxygen, and/or argon, such as pure hydrogen or a combination of a first gas flow of argon and a second gas flow of hydrogen or oxygen at any flow rate ratio of hydrogen or oxygen to argon, such as a flow rate ratio of hydrogen/oxygen:argon that is within a range of 1:350 to 150:1. In one embodiment, which can be combined with other embodiments, the first gas flow flows argon at a flow rate within a range of 10 sccm to 3,500 sccm to ignite plasma, and then the second gas flow flows hydrogen or oxygen at a flow rate within a range of 10 sccm to 1,500 sccm to provide hydrogen plasma or oxygen plasma.

The RPS's 306A, 306B respectively generate hydrogen radicals using the gas, and supplies the hydrogen radicals to the respective second processing volumes 308A, 308B and to the first substrate 270 and the second substrate 271 during a radical treatment operation to clean the first and second substrates 270, 271 and reduce or remove the contaminant particles 277 from the film stacks 272 and the first and second substrates 270, 271. The present disclosure contemplates that the second substrate 271 can include film stacks similar to the film stacks 272 of the first substrate 270. The system 300 can include one or more ion filters that filter out ions from the plasma generated using the RPSs 306A, 306B. The present disclosure contemplates that the RPS's 306A, 306B can generate one or more plasma materials other than hydrogen radicals.

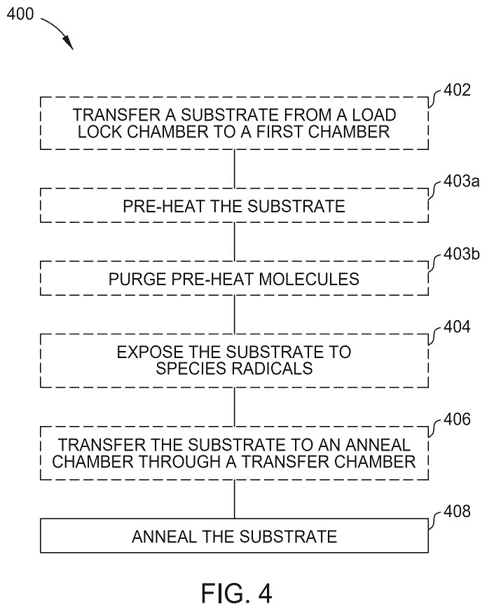

FIG. 4 is a schematic block diagram view of a method 400 of substrate processing for semiconductor manufacturing, according to one or more embodiments.

A substrate is positioned in a load lock chamber. Optional operation 402 includes transferring the substrate from the load lock chamber and to a first process volume of a first chamber.

Optional operation 403a includes pre-heating the substrate. The pre-heating of the substrate includes exposing the substrate to pre-heat hydrogen molecules.

Optional operation 403b includes purging the pre-heat hydrogen molecules at a purge pressure. In one or more embodiments, the purge pressure is within a range of 15 Torr to 530 Torr, such 15 Torr to 20 Torr. In one or more examples, a purge gas including hydrogen may be utilized at a purge pressure of 15 Torr to 20 Torr. In one or more examples, a purge gas including argon may be utilized at a pressure within a range of 15 Torr to about 530 Torr. In one or more embodiments, the purge pressure is 18 Torr. In one or more embodiments, the purge pressure is within a range of 500 Torr to 550 Torr. In one or more embodiments, the purge pressure is 530 Torr.

Optional operation 404 includes exposing the substrate to species radicals. The exposing of the substrate to the species radicals includes a treatment temperature that is less than 350 degrees Celsius, such as less than 300 degrees Celsius, a treatment pressure that is less than 1.0 Torr, and a treatment time that is within a range of 8.0 minutes to 12.0 minutes. In one embodiment or more embodiments, the treatment temperature is within a range of 150 degrees Celsius to 250 Celsius degrees, such as 175 degrees Celsius to 225 degrees Celsius, such as 195 degrees Celsius to 205 degrees Celsius, the treatment pressure is within a range of 0.35 Torr to 0.45 Torr, and the treatment time is within a range of 1 minute to 60 minutes, such as 2 minutes to 30 minutes, such as 2 minutes to 15 minutes, such as 2 minutes to 12 minutes, for example 9.5 minutes to 10.5 minutes. In one or more embodiments, the treatment pressure is 0.4 Torr. In one or more embodiments, the treatment temperature is 200 degrees Celsius, and the treatment time is 10 minutes. Other process parameter values are contemplated.

The species radicals are supplied to the first internal volume at a flow rate within a range of 1,300 SCCM to 1,400 SCCM for a 300 mm diameter substrate. In one or more embodiments, the flow rate is 1,350 SCCM. In one or more embodiments, the species radicals include atomic hydrogen radicals. In one or more embodiments, the species radicals include one or more of oxygen (O₂), nitrogen (N₂), and/or helium (He). Other process parameter values are contemplated.

The species radicals of operation 404 can be generated using one or more of a remote plasma source (RPS), an inductively coupled plasma (ICP) source, and/or one or more microwave resonators for in-situ generation.

Optional operation 406 includes transferring the substrate from the first process volume of the first chamber and to a second process volume of a second chamber through a transfer volume of a transfer chamber. The transfer volume of the transfer chamber is maintained at a transfer pressure that is within a range of 500 Torr to 550 Torr. The second chamber can be, for example, an anneal chamber. The transferring can position the substrate on a substrate support (such as the pedestal heater 230) of the anneal chamber.

During the transferring of the substrate into and out of the first chamber (such as the transferring of operation 402 and/or the transferring of operation 406), argon (Ar) is supplied as a purge gas to the first process volume of the first chamber at a first transfer pressure and a first transfer flow rate. In one or more embodiments, the first transfer pressure is within a range of 16 Torr to 20 Torr and the first transfer flow rate is within a range of 2.5 liters per minute (LPM) to 3.5 LPM. In one or more embodiments, the first transfer pressure is 18 Torr and the first transfer flow rate is 3.0 LPM. In one or more embodiments, the first transfer pressure is within a range of 500 Torr to 550 Torr and the first transfer flow rate is within a range of 10.0 LPM to 12.0 LPM. In one or more embodiments, the first transfer pressure is 530 Torr and the first transfer flow rate is 11.0 LPM. In one or more embodiments, the first transfer pressure is within a range of 500 Torr to 550 Torr and the first transfer flow rate is within a range of 24.0 LPM to 26.0 LPM. In one or more embodiments, the first transfer pressure is 530 Torr and the first transfer flow rate is 25.0 LPM. Other process parameter values are contemplated.

During one or more first buffer periods (such as one or more first downtime periods) for the first chamber, nitrogen (N₂) is supplied to the first process volume of the first chamber at a first buffer pressure and a first buffer flow rate. In one or more embodiments, the first buffer pressure is within a range of 15 Torr to 20 Torr and the first buffer flow rate is within a range of 2.5 LPM to 3.5 LPM. In one or more embodiments, the first buffer pressure is 18 Torr and the first buffer flow rate is 3.0 LPM. In one or more embodiments, the first buffer pressure is within a range of 500 Torr to 550 Torr and the first buffer flow rate is within a range of 40.0 LPM to 50.0 LPM. In one or more embodiments, the first buffer pressure is 530 Torr and the first buffer flow rate is 45.0 LPM. In one or more embodiments, the first buffer pressure is 530 Torr and the first buffer flow rate is 50.0 LPM. Other process parameter values are contemplated.

During the transferring of the substrate into and out of the second chamber (such as the transferring of operation 406), nitrogen (N₂) is supplied as a purge gas to the second process volume of the second chamber at a second transfer pressure and a second transfer flow rate. In one embodiment, which can be combined with other embodiments, the second transfer pressure is within a range of 500 Torr to 550 Torr and the second transfer flow rate is within a range of 14.0 LPM to 16.0 LPM. In one embodiment, which can be combined with other embodiments, the second transfer pressure is 530 Torr and the second transfer flow rate is 15.0 LPM.

During one or more second buffer periods (such as one or more second downtime periods) for the second chamber, nitrogen (N₂) is supplied to the second process volume of the second chamber at a second buffer pressure and a second buffer flow rate. In one embodiment, which can be combined with other embodiments, the second buffer pressure is within a range of 500 Torr to 550 Torr and the second buffer flow rate is within a range of 40.0 LPM to 50.0 LPM. In one embodiment, which can be combined with other embodiments, the second buffer pressure is 530 Torr and the second buffer flow rate is 45.0 LPM. In one embodiment, which can be combined with other embodiments, the second buffer pressure is 530 Torr and the second buffer flow rate is 50.0 LPM.

Operation 406 can include an air break period where the substrate is exposed to ambient air prior to being transferred into the second process volume of the second chamber. In one or more embodiments, the air break period occurs while the substrate is positioned in-situ in the cluster tool 180. In one or more embodiments, the air break period is within a range of 55.0 minutes to 65.0 minutes, such as 60.0 minutes.

Operation 408 includes annealing the substrate. The annealing can occur after the exposing of the substrate to the species radicals of optional operation 404. The annealing includes exposing the substrate to a plasma, exposing the substrate to an anneal temperature and an anneal pressure, and exposing the substrate for an anneal time that is less than 4.0 minutes. In one or more embodiments, the anneal temperature is less than 210 degrees Celsius. In one or more embodiments, the anneal temperature is 175 degrees Celsius or less, for example 150 degrees Celsius or less, or 130 degrees Celsius or less. In one or more embodiments, the anneal time is within a range of 1.5 minutes to 2.5 minutes, such as about 2.0 minutes. In one or more embodiments, the anneal pressure is within a range of 500 Torr to 550 Torr, such as 525 Torr to 535 Torr.

The plasma of the annealing can include species (such as the species described herein), for example species radicals and/or species ions. In one or more embodiments, the annealing environment includes hydrogen (H₂). In one or more embodiments, the annealing environment additionally or alternatively includes one or more of hydrogen (H₂), dinitride (N₂), and/or ammonia (NH₃).

During the annealing of operation 408, the substrate can be heated using one or more lamp heaters and/or one or more resistive heaters that heat a pedestal on which the substrate is supported. During the annealing a power level for the one or more heater elements is less than 10%. In one or more embodiments, the power level is 5% or less, for example about 2.5%.

The present disclosure contemplates that the method 400 can be conducted after other semiconductor processing operations, such as after a deposition operation (e.g., a chemical vapor deposition (CVD) operation), an etching operation, and/or a lithography operation.

The pre-heating of the substrate (of operation 403a) and the exposing of the substrate to the hydrogen radicals (of operation 404) occurs in the first process volume of the first chamber, and the annealing of the substrate (of operation 408) occurs in the second process volume of the second chamber. The first chamber and the second chamber are coupled to a mainframe of a single cluster tool.

The present disclosure contemplates that the operations 402, 403a, 403b, 404, 406, 408 can be repeated on the substrate being processed. The conducting of the method 400 in one or more iterations reduces a sheet resistance of one or more metals of the substrate. In one or more embodiments, the one or more metals include one or more of copper (Cu), ruthenium (Ru), and/or dinitride (N₂).

The present disclosure contemplates that operations 402, 403a, 403b, 404 can be omitted from the method 400, and the method 400 can include operations 406 and 408. In such an embodiment, the substrate can be transferred into the anneal chamber from a chamber other than the first chamber, such as from the load lock chamber or a deposition chamber.

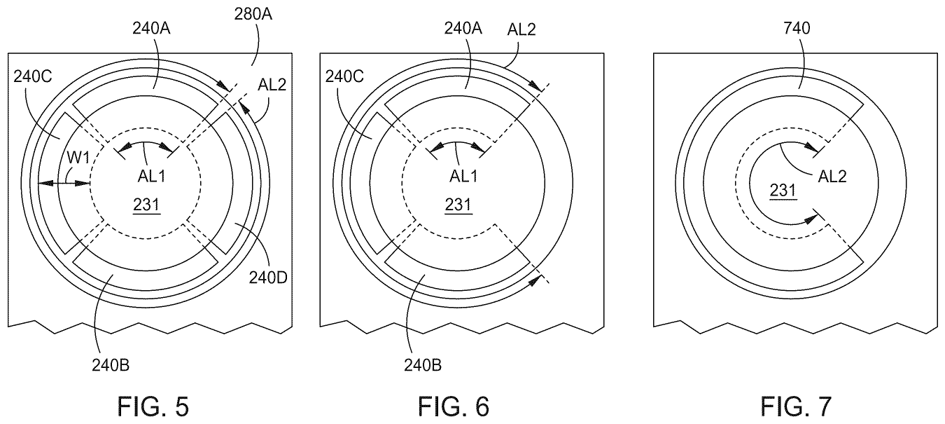

FIG. 5 is a schematic partial top view of a plurality of liners 240A-240D in the processing region 228A, to one or more embodiments.

The one or more liners 240A-240D respectively include a body having an azimuthal length AL1 that is 80 degrees or higher. In one or more embodiments, the azimuthal length AL1 is 85 degrees or higher, such as 90 degrees or higher). In one or more embodiments, the body includes a ring or a ring segment. The ring or ring segment can be curved (such as arcuate or circular) in shape, and/or rectangular (such as square) in shape. The plurality of liners 240A-240D can span an azimuthal length AL2 that is 180 degrees or higher. In one or more embodiments, the azimuthal length AL2 is 220 degrees or higher, such as 260 degrees or higher.

FIG. 6 is a schematic partial top view of a plurality of liners 240A-240C in the processing region 228A, according to one or more embodiments.

The plurality of liners 240A-240D are respectively removable for modularity and/or thermal adjustability. In the implementation shown in FIG. 6, the liner 240D on the side corresponding to the slit valve corresponding to the processing region 228A is removed and/or omitted.

FIG. 7 is a schematic top view of a C-ring liner 740 in the processing region 228A, according to one or more embodiments.

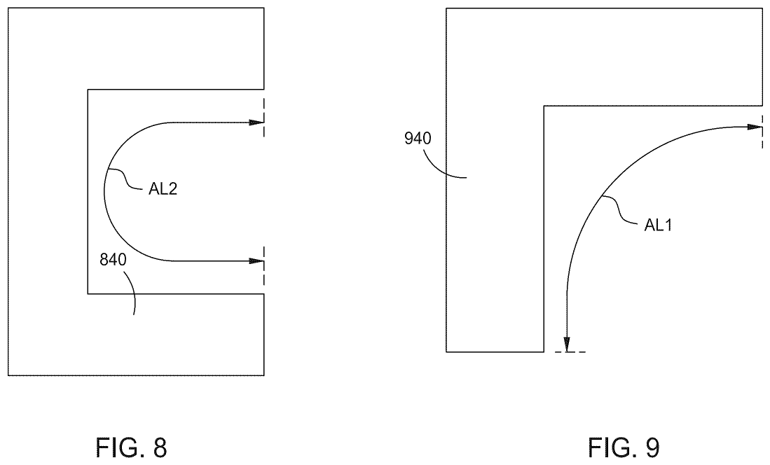

At least one liner (such as the C-ring liner 740) of one or more liners described herein can have the azimuthal length AL2 that is 180 degrees or higher. The liners herein can be curved (as shown in FIG. 7) and/or rectangular (as shown in FIG. 8) in shape.

FIG. 8 is a schematic top view of a C-ring liner 840, according to one or more embodiments.

FIG. 9 is a schematic top view of an L-shaped liner 940, according to one or more embodiments. The various liners 740, 840, 940 can be used in place of one or more of the liners 240A-240D described herein.

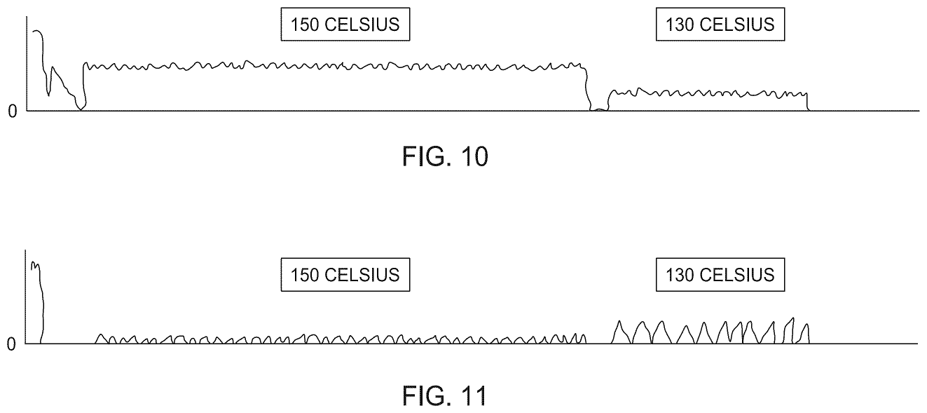

FIG. 10 is a schematic power-versus-time graph for power of a heater (such as an outer heater corresponding to an edge region of a substrate) for a chamber using liners described herein, according to one or more embodiments.

FIG. 11 is a schematic power-versus-time graph for power of a heater (such as an outer heater corresponding to an edge region of a substrate) for a chamber using another configuration.

FIGS. 10 and 11 respectively show a first section corresponding to an annealing temperature of 150 degrees Celsius, and a second section corresponding to an annealing temperature of 130 degrees Celsius. By comparing FIG. 11 with FIG. 10, the liners described herein facilitate heating efficiency, temperature uniformity, and device performance. For example, at relatively low temperatures (such as 150 degrees Celsius and 130 degrees Celsius) FIG. 10 shows the power oscillating without reaching a zero power level (thus exhibiting enhanced power stability), whereas in FIG. 11 the power oscillates repeatedly to a zero level.

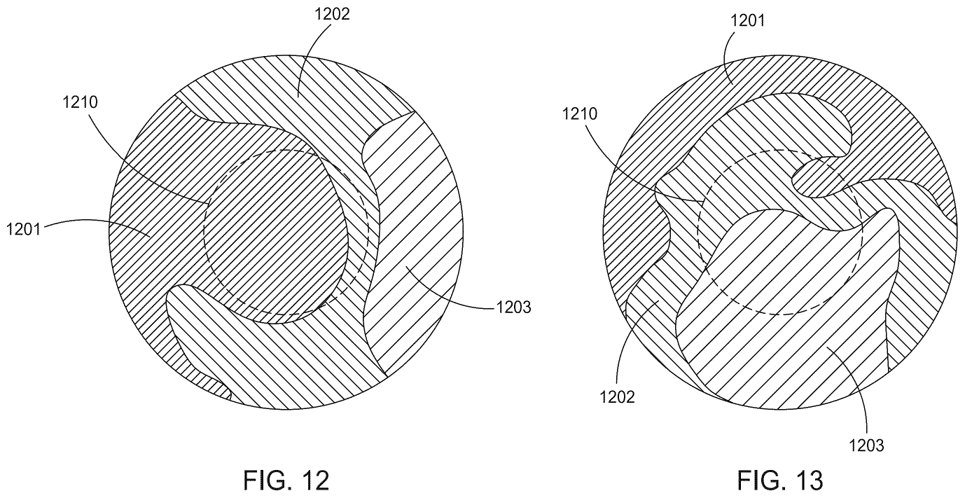

FIG. 12 is a schematic temperature map of a substrate annealed in a chamber using liners described herein, according to one or more embodiments.

The temperature map includes a hot zone 1201, an intermediate zone 1202, and a cold zone 1203. A boundary 1210 is marked between an inner region of the substrate and an outer region of the substrate.

FIG. 13 is a schematic temperature map of a substrate annealed in a chamber another configuration.

The temperature map includes a hot zone 1301, an intermediate zone 1302, and a cold zone 1303.

By comparing FIG. 13 with FIG. 12, the liners described herein facilitate thermal adjustability. For example, in FIG. 12 most of the inner region (e.g. a central region) of the substrate has the lower temperatures of the intermediate zone 1202 and the cold zone 1203, whereas in FIG. 13 most of the inner region of the substrate has the higher temperature of the hot zone 1201 such that the inner region is hotter than the outer region (such as the edge region). As an example, the emissivity of the one or more liners 240A, 240B can draw heat from the outer region (e.g., the edge region) of the substrate to facilitate the temperature map in FIG. 12. In one or more embodiments, during the annealing of FIG. 12 a temperature difference between the inner region (e.g., the central region) and the outer region (e.g., the edge region) of the substrate is 10 degrees Celsius or less. In one or more embodiments, the temperature difference is 5 degrees Celsius or less, such as 2 degrees Celsius or less. Other temperature differences are contemplated. For example, not be bound by theory, it is believed that more of the central region including the hot zone 1201 (FIG. 12) can allow for larger temperature differences.

Benefits of the present disclosure include thermal adjustability and uniformity (such as center-to-edge adjustability and uniformity); low temperature processing (such as annealing at temperatures less than 210 degrees Celsius, such as 175 degrees Celsius or less) while facilitating uniformity and adjustability of center-to-edge temperature differences; effective and reliable control of heaters and edge regions of substrates. For example, the edge regions of substrates can be controlled to be colder than central regions of substrates. As another example, larger center-to-edge temperature differences may be used to facilitate adjustability while facilitating low temperature processing and/or uniform processing. As a further example, the liners described herein (which have sizes and high emissivity values) facilitate using heating power for the outer substrate regions (e.g., edge regions) so that heater powers maintain above a zero level at low processing temperatures. The emissive liners can pull heat from the outer edge of the substrate support and/or the substrate to facilitate the edge region of the substrate being cooler than the central region of the substrate. The emissive liners can pull heat from the outer edge of the substrate support and/or the substrate to facilitate a reduced center-to-edge temperature difference. The emissive liners can pull heat from the outer edge of the substrate support and/or the substrate to facilitate an increased power for a more stable power supply for heater(s) in low temperature processing. Such benefits can be facilitated, for example, for substrate supports that include dual-zone ceramic heaters.

Such benefits can be achieved on a single mainframe of a single integrated cluster tool, facilitating increased efficiencies, reduced footprints, reduced costs, and increased output.

It is contemplated that one or more aspects disclosed herein may be combined. As an example, one or more aspects, features, components, and/or properties of the claims herein, the system 100, the cluster tool 180, the system 200, the system 300, the method 400, the one or more liners 240A-240D, the one or more liners 740, the one or more liners 840, the one or more liners 940, the information of FIG. 10, and/or the information of FIG. 12 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

1. A processing chamber, comprising:
a chamber body at least partially defining a process volume;
a substrate support disposed in the process volume, the substrate support comprising one or more heater elements;
one or more liners disposed between the substrate support and a section of the chamber body, the one or more liners respectively including a ring or a ring segment having an azimuthal length that is 80 degrees or higher; and
a plasma source operable to supply a plasma to the process volume.

2. The processing chamber of claim 1, wherein the section is a floor section of the chamber body.

3. The processing chamber of claim 2, wherein the one or more liners directly contact the floor section.

4. The processing chamber of claim 1, wherein the one or more liners are radially aligned with an outer edge of the substrate support.

5. The processing chamber of claim 4, wherein an inner section of the respective one or more liners is aligned under the substrate support, and an outer section of the respective one or more liners is aligned radially outwardly of the substrate support.

6. The processing chamber of claim 1, wherein the one or more liners have an emissivity that is 0.75 or higher.

7. The processing chamber of claim 1, wherein the one or more liners are formed of anodized aluminum.

8. The processing chamber of claim 1, wherein the one or more liners respectively have a width that is greater than a thickness, the width is a ratio of the thickness, and the ratio is at least 2.0.

9. The processing chamber of claim 8, wherein the thickness is within a range of 0.25 inches to 0.5 inches.

10. The processing chamber of claim 1, wherein the one or more liners include a liner having an azimuthal length that is 180 degrees or higher.

11. The processing chamber of claim 1, wherein the one or more liners include a plurality of liners that are respectively removable for modularity.

12. A liner for disposition in a processing chamber, the liner comprising:
a body having an azimuthal length that is 80 degrees or higher, the body formed of an anodized aluminum, the body having a width that is greater than a thickness, the width is a ratio of the thickness, and the ratio is at least 2.0.

13. The liner of claim 12, wherein the body is curved in shape.

14. The liner of claim 12, wherein the body has an emissivity that is 0.75 or higher.

15. The liner of claim 12, wherein the thickness is within a range of 0.25 inches to 0.5 inches.

16. The liner of claim 12, wherein the body is a C-ring or an L-ring having an azimuthal length that is 180 degrees or higher.

17. A system for processing substrates, comprising:
a processing chamber, comprising:
a chamber body at least partially defining a process volume,
a substrate support disposed in the process volume, the substrate support comprising one or more heater elements,
one or more liners disposed between the substrate support and a section of the chamber body, and
a plasma source; and
a controller comprising a processor and a memory comprising instructions that, when executed by the processor, cause a plurality of operations to be conducted, the plurality of operations comprising:
positioning a substrate on the substrate support,
annealing the substrate, the annealing comprising:
exposing the substrate to a plasma,
exposing the substrate to an anneal temperature that is less than 210 degrees Celsius, and
exposing the substrate for an anneal time that is less than 4.0 minutes.

18. The system of claim 17, wherein during the annealing a temperature difference between a central region and an edge region of the substrate is 10 degrees Celsius or less.

19. The system of claim 17, wherein wherein the one or more liners have an emissivity that is 0.75 or higher to draw heat from an edge region of the substrate.

20. The system of claim 17, wherein during the annealing a power level for the one or more heater elements is less than 10%.
